(19) United States
(12) Patent Application Publication
(10) Pub. No.: US 2024/0036120 A1
(43) Pub. Date: Feb. 1, 2024

(54) DETECTION AND GATING MODULE, BATTERY MANAGEMENT SYSTEM AND BATTERY MANAGEMENT CHIP

(71) Applicant: ZHUHAI MAIJU MICROELECTRONICS CO., LTD., Zhuhai (CN)

(72) Inventor: Hao ZHOU, Zhuhai (CN)

(73) Assignee: ZHUHAI MAIJU MICROELECTRONICS CO., LTD., Zhuhai (CN)

(21) Appl. No.: 18/267,153

(22) PCT Filed: Jun. 16, 2021
(86) PCT No.: PCT/CN2021/100250

§ 371 Date: Jul. 20, 2023

(30) Foreign Application Priority Data
Dec. 14, 2020 (CN) 202011467697.5

(51) Int. Cl. G01R 31/396; G01R 1/30; G01R 31/3835

(52) U.S. Cl. CPC G01R 31/396; G01R 1/30; G01R 31/3835

(57) ABSTRACT

A detection and gating module in a battery management system is provided, where the detection and gating module is configured to detect a voltage of each battery in a battery pack containing N batteries connected in series, N≥1, and the detection and gating module includes: N gating switches, where an i^{th} gating switch of the N gating switches is connected to a positive terminal of an i^{th} battery of the N batteries, a voltage of the i^{th} battery is detected when the i^{th} gating switch is turned on, and 1≤i≤N; N protection circuits, where an i^{th} protection circuit of the N protection circuits is configured to protect the i^{th} gating switch of the N gating switches; and N voltage generation circuits.

### CROSS REFERENCE TO THE RELATED APPLICATIONS

This application is the national phase entry of International Application No. PCT/CN2021/100250, filed on Jun. 16, 2021, which is based upon and claims priority to Chinese Patent Application No. 202011467697.5, filed on Dec. 14, 2020, the entire contents of which are incorporated herein by reference.

### TECHNICAL FIELD

The present disclosure relates to a detection and gating module, a battery management system, and a battery management chip.

### BACKGROUND

In a battery management system, it is necessary to measure the voltage of each battery. Usually, a gating circuit is used to select a to-be-measured battery, and then an analog-to-digital converter is used to convert a collected voltage into a digital signal and provide the digital signal for a controller. The controller manages the battery based on the collected voltage signal, for example, the controller may control a charging/discharging switch.

In the present disclosure, a technical solution is proposed to accurately control the gating circuit and reliably measure the voltage of each battery.

### SUMMARY

In order to resolve one of the above technical problems, the present disclosure provides a detection and gating module, a battery management system, and a battery management chip.

According to an aspect of the present disclosure, a detection and gating module in a battery management system is provided, where the detection and gating module is configured to detect a voltage of each battery in a battery pack containing N batteries connected in series, N≥1, and the detection and gating module includes:
N gating switches, where an i^{th} gating switch of the N gating switches is connected to a positive terminal of an i^{th} battery of the N batteries, a voltage of the i^{th} battery is detected when the i^{th} gating switch is turned on, and 1≤i≤N;
N protection circuits, where an i^{th} protection circuit of the N protection circuits is configured to protect the i^{th} gating switch of the N gating switches; and
N voltage generation circuits, where an i^{th} voltage generation circuit of the N voltage generation circuits is configured to generate a turn-on voltage for turning on the i^{th} gating switch of the N gating switches and a turn-off voltage for turning off the i^{th} gating switch.

According to the detection and gating module in at least one implementation of the present disclosure, when the voltage of the i^{th} battery is detected, battery voltages at both ends of the i^{th} battery are detected by turning on the i^{th} gating switch and an (i−1)^{th} gating switch.

According to the detection and gating module in at least one implementation of the present disclosure, the i^{th} gating switch includes a first transistor and a second transistor, a drain of the first transistor is connected to a battery voltage at the positive terminal of the i^{th} battery, a source of the first transistor is connected to a source of the second transistor, a gate of the first transistor is connected to a gate of the second transistor, and a drain of the second transistor outputs a sampled battery voltage.

According to the detection and gating module in at least one implementation of the present disclosure, the i^{th} protection circuit is a protection diode, a cathode of the i^{th} protection diode is connected to the sources of the first transistor and the second transistor of the i^{th} gating switch, and an anode of the i^{th} protection diode is connected to the gates of the first transistor and the second transistor of the i^{th} gating switch.

According to the detection and gating module in at least one implementation of the present disclosure, when the voltage of the i^{th} battery is detected, a control voltage higher than the battery voltage at the positive terminal of the i^{th} battery by a predetermined voltage is generated by the i^{th} voltage generation circuit to turn on the first transistor and the second transistor of the i^{th} gating switch, and a control voltage higher than a battery voltage at a positive terminal of an (i−1)^{th} battery by the predetermined voltage is generated by an (i−1)^{th} voltage generation circuit to turn on a first transistor and a second transistor of the (i−1)^{th} gating switch; and when the voltage of the i^{th} battery is not detected, a control voltage lower than the battery voltage at the positive terminal of the i^{th} battery is generated by the i^{th} voltage generation circuit to turn off the first transistor and the second transistor of the i^{th} gating switch, and a control voltage lower than the battery voltage at the positive terminal of the (i−1)^{th} battery is generated by the (i−1)^{th} voltage generation circuit to turn off the first transistor and the second transistor of the (i−1)^{th} gating switch.

According to the detection and gating module in at least one implementation of the present disclosure, when the voltage of the i^{th} battery is detected, a turn-on voltage for turning on the first transistor and the second transistor of the i^{th} gating switch is generated by the i^{th} voltage generation circuit, and a turn-on voltage for turning on a first transistor and a second transistor of the (i−1)^{th} gating switch is generated by an (i−1)^{th} voltage generation circuit; and
when the voltage of the i^{th} battery is not detected, a turn-off voltage for turning off the first transistor and the second transistor of the i^{th} gating switch is generated by the i^{th} voltage generation circuit, and a turn-off voltage for turning off the first transistor and the second transistor of the (i−1)^{th} gating switch is generated by the (i−1)^{th} voltage generation circuit.

According to the detection and gating module in at least one implementation of the present disclosure, the i^{th} voltage generation circuit includes a capacitor, the control voltage is provided by charging and discharging of the capacitor, to turn on or off the first transistor and the second transistor of the i^{th} gating switch.

According to the detection and gating module in at least one implementation of the present disclosure, the i^{th} voltage generation circuit includes:
a drain of a first N-channel metal oxide semiconductor (NMOS) transistor is connected to a highest voltage of the battery pack, a gate of the first NMOS transistor is connected to the battery voltage at the positive terminal of the i^{th} battery, a source of the first NMOS transistor is connected to a drain of a second NMOS transistor, the source of the first NMOS transistor is connected to a cathode of a second diode, the gate of the first NMOS transistor is connected to an anode of the second diode, a source of the second NMOS transistor is grounded, a drain of a third NMOS transistor is connected to a constant current source, the drain of the third NMOS transistor is connected to a gate of the third NMOS transistor, the gate of the third NMOS transistor is connected to one terminal of a first switch, the other terminal of the first switch is connected to a gate of the second NMOS transistor, the gate of the second NMOS transistor is connected to one terminal of a second switch, the other terminal of the second switch is grounded, the drain of the third NMOS transistor is connected to one terminal of a third switch, the other terminal of the third switch is connected to a gate of a fourth NMOS transistor, a source of the fourth NMOS transistor is grounded, the gate of the fourth NMOS transistor is connected to one terminal of a fourth switch, the other terminal of the fourth switch is grounded, a gate of a first p-channel metal oxide semiconductor (PMOS) transistor is connected to the source of the first NMOS transistor, a source of the first PMOS transistor is connected to the battery voltage at the positive terminal of the i^{th} battery, a drain of the first PMOS transistor is connected to a drain of the fourth NMOS transistor, the drain of the fourth NMOS transistor is connected to a bottom plate of the capacitor, a top plate of the capacitor is connected to an anode of a first diode, a cathode of the first diode is connected to a supply voltage, and the top plate of the capacitor is connected to the anode of the protection diode.

According to the detection and gating module in at least one implementation of the present disclosure, the i^{th} voltage generation circuit includes:
a drain of a first NMOS transistor is connected to a highest voltage of the battery pack, a gate of the first NMOS transistor is connected to the battery voltage at the positive terminal of the i^{th} battery, a source of the first NMOS transistor is connected to a cathode of a first diode, the gate of the first NMOS transistor is connected to an anode of the first diode, the source of the first NMOS transistor is connected to a drain of a second NMOS transistor, a source of the second NMOS transistor is grounded, a drain of a third NMOS transistor is connected to a constant current source, the drain of the third NMOS transistor is connected to a gate of the third NMOS transistor, the gate of the third NMOS transistor is connected to one terminal of a first switch, the other terminal of the first switch is connected to a gate of the second NMOS transistor, the gate of the second NMOS transistor is connected to one terminal of a second switch, the other terminal of the second switch is grounded, the drain of the third NMOS transistor is connected to one terminal of a third switch, the other terminal of the third switch is connected to a gate of a fourth NMOS transistor, a source of the fourth NMOS transistor is grounded, the gate of the fourth NMOS transistor is connected to one terminal of a fourth switch, the other terminal of the fourth switch is grounded, a gate of a first PMOS transistor is connected to a gate of a second PMOS transistor, the gate of the first PMOS transistor is connected to a drain of the first PMOS transistor, a source of the first PMOS transistor and a source of the second PMOS transistor are connected to the highest voltage of the battery pack, the drain of the first PMOS transistor is connected to a drain of the fourth NMOS transistor, a drain of the second PMOS transistor is connected to a source of a third PMOS transistor, a gate of the third PMOS transistor is connected to the battery voltage at the positive terminal of the i^{th} battery, a drain of the third PMOS transistor is grounded, the drain of the second NMOS transistor is connected to the anode of the protection diode, and the source of the third PMOS transistor is connected to the anode of the protection diode.

According to the detection and gating module in at least one implementation of the present disclosure, the i^{th} voltage generation circuit comprises a fifth NMOS transistor, a drain of the fifth NMOS transistor is connected to the gates of the first transistor and the second transistor, a source of the fifth NMOS transistor is connected to the sources of the first transistor and the second transistor, and a gate of the fifth NMOS transistor is connected to the drain of the fifth NMOS transistor to provide the control voltage through turn-on or turn-off of the fifth NMOS transistor, so as to turn on or off the first transistor and the second transistor of the i^{th} gating switch.

According to the detection and gating module in at least one implementation of the present disclosure, the i^{th} voltage generation circuit includes:
a source of a first PMOS transistor and a source of a second PMOS transistor are connected to a highest voltage of the battery pack, a gate of the first PMOS transistor is connected to a drain of the first PMOS transistor, the gate of the first PMOS transistor is connected to a gate of the second PMOS transistor to form a mirror circuit, the drain of the first PMOS transistor is connected to a drain of a first NMOS transistor, a source of the first NMOS transistor is grounded, a drain of a second NMOS transistor is connected to a constant current source, the drain of the second NMOS transistor is connected to a gate of the second NMOS transistor, a source of the second NMOS transistor is grounded, the gate of the second NMOS transistor is connected to one terminal of a first switch, the other terminal of the first switch is connected to a gate of the first NMOS transistor, one terminal of a second switch is connected to the gate of the first NMOS transistor, the other terminal of the second switch is grounded, the drain of the second NMOS transistor is connected to one terminal of a third switch, the other terminal of the third switch is connected to a gate of a third NMOS transistor, one terminal of a fourth switch is connected to the gate of the third NMOS transistor, the other terminal of the fourth switch is grounded, the drain of the second NMOS transistor is connected to one terminal of a fifth switch, the other terminal of the fifth switch is connected to a gate of a fourth NMOS transistor, one terminal of a sixth switch is connected to the gate of the fourth NMOS transistor, the other terminal of the sixth switch is grounded, a drain of the third NMOS transistor is connected to the source of the fifth NMOS transistor and to the sources of the first transistor and the second transistor, a drain of the fourth NMOS transistor is connected to the drain of the fifth NMOS transistor and to the gates of the first transistor and the second transistor, a drain of the second PMOS transistor is connected to the drain of the fifth NMOS transistor, and the gate of the fifth NMOS transistor is connected to the drain of the fifth NMOS transistor.

According to the detection and gating module in at least one implementation of the present disclosure, the i^{th} voltage generation circuit includes a third PMOS transistor, a source of the third PMOS transistor is connected to the gates of the first transistor and the second transistor, a drain of the third PMOS transistor is connected to the sources of the first transistor and the second transistor, and a gate of the third PMOS transistor is connected to the drain of the third PMOS transistor to provide the control voltage through turn-on or turn-off of the third PMOS transistor, so as to turn on or off the first transistor and the second transistor of the i^{th} gating switch.

According to the detection and gating module in at least one implementation of the present disclosure, the i^{th} voltage generation circuit includes:
a source of a first PMOS transistor and a source of a second PMOS transistor are connected to a highest voltage of the battery pack, a gate of the first PMOS transistor is connected to a drain of the first PMOS transistor, the gate of the first PMOS transistor is connected to a gate of the second PMOS transistor to form a mirror circuit, the drain of the first PMOS transistor is connected to a drain of a first NMOS transistor, a source of the first NMOS transistor is grounded, a drain of a second NMOS transistor is connected to a constant current source, the drain of the second NMOS transistor is connected to a gate of the second NMOS transistor, a source of the second NMOS transistor is grounded, the gate of the second NMOS transistor is connected to one terminal of a first switch, the other terminal of the first switch is connected to a gate of the first NMOS transistor, one terminal of a second switch is connected to the gate of the first NMOS transistor, the other terminal of the second switch is grounded, the drain of the second NMOS transistor is connected to one terminal of a third switch, the other terminal of the third switch is connected to a gate of a third NMOS transistor, one terminal of a fourth switch is connected to the gate of the third NMOS transistor, the other terminal of the fourth switch is grounded, the drain of the second NMOS transistor is connected to one terminal of a fifth switch, the other terminal of the fifth switch is connected to a gate of a fourth NMOS transistor, one terminal of a sixth switch is connected to the gate of the fourth NMOS transistor, the other terminal of the sixth switch is grounded, a drain of the third NMOS transistor is connected to the drain of the third PMOS transistor and to the sources of the first transistor and the second transistor, a drain of the fourth NMOS transistor is connected to the source of the third PMOS transistor and to the gates of the first transistor and the second transistor, a drain of the second PMOS transistor is connected to the source of the third PMOS transistor, and the gate of the third PMOS transistor is connected to the drain of the third PMOS transistor.

According to the detection and gating module in at least one implementation of the present disclosure, the i^{th} voltage generation circuit is the protection diode, and the control voltage is provided by using a reverse breakdown voltage when the protection diode is broken down reversely, to turn on or off the first transistor and the second transistor of the i^{th} gating switch.

According to the detection and gating module in at least one implementation of the present disclosure, the i^{th} voltage generation circuit includes:
a source of a first PMOS transistor and a source of a second PMOS transistor are connected to a highest voltage of the battery pack, a gate of the first PMOS transistor is connected to a drain of the first PMOS transistor, the gate of the first PMOS transistor is connected to a gate of the second PMOS transistor to form a mirror circuit, the drain of the first PMOS transistor is connected to a drain of a first NMOS transistor, a source of the first NMOS transistor is grounded, a drain of a second NMOS transistor is connected to a constant current source, the drain of the second NMOS transistor is connected to a gate of the second NMOS transistor, a source of the second NMOS transistor is grounded, the gate of the second NMOS transistor is connected to one terminal of a first switch, the other terminal of the first switch is connected to a gate of the first NMOS transistor, one terminal of a second switch is connected to the gate of the first NMOS transistor, the other terminal of the second switch is grounded, the drain of the second NMOS transistor is connected to one terminal of a third switch, the other terminal of the third switch is connected to a gate of a third NMOS transistor, one terminal of a fourth switch is connected to the gate of the third NMOS transistor, the other terminal of the fourth switch is grounded, the drain of the second NMOS transistor is connected to one terminal of a fifth switch, the other terminal of the fifth switch is connected to a gate of a fourth NMOS transistor, one terminal of a sixth switch is connected to the gate of the fourth NMOS transistor, the other terminal of the sixth switch is grounded, a drain of the third NMOS transistor is connected to the sources of the first transistor and the second transistor, a drain of the fourth NMOS transistor is connected to the gates of the first transistor and the second transistor, and a drain of the second PMOS transistor is connected to the gates of the first transistor and the second transistor.

According to another aspect of the present disclosure, a battery management system includes:
the detection and gating module described above, where the detection and gating module is configured to detect a voltage of each battery in a battery pack containing N batteries connected in series; and
a voltage amplification module configured to receive the voltage of each battery that is output by the detection and gating module, to amplify and output the voltage of each battery.

The battery management system according to at least one implementation of the present disclosure further includes:
an analog-to-digital conversion module configured to perform analog-to-digital conversion on the voltage of each battery from the voltage amplification module; and
a control logic module configured to receive a battery voltage converted by the analog-to-digital conversion module, and provide a control signal for a switch driving module at least based on the converted battery voltage, so as to control turn-on or turn-off of a discharging switch and a charging switch by using the switch driving module.

According to still another aspect of the present disclosure, a battery management chip is integrated with the battery management system described above.

### BRIEF DESCRIPTION OF THE DRAWINGS

The accompanying drawings illustrate exemplary implementations of the present disclosure, and are intended to explain the principle of the present disclosure together with the description thereof. The accompanying drawings are provided to provide a further understanding of the present disclosure, and are included in and constitute part of the specification.

FIG. 1 is a schematic diagram of a battery management system according to an implementation of the present disclosure;

FIG. 2 is a schematic diagram of a detection and gating module according to an implementation of the present disclosure;

FIG. 3 is a schematic diagram of a gating and detection switch and corresponding control according to an implementation of the present disclosure;

FIG. 4 is an example circuit diagram of a gating and detection switch and corresponding control according to an implementation of the present disclosure;

FIG. 5 is an example circuit diagram of a gating and detection switch and corresponding control according to an implementation of the present disclosure;

FIG. 6 is an example circuit diagram of a gating and detection switch and corresponding control according to an implementation of the present disclosure;

FIG. 7 is an example circuit diagram of a gating and detection switch and corresponding control according to an implementation of the present disclosure; and

FIG. 8 is an example circuit diagram of a gating and detection switch and corresponding control according to an implementation of the present disclosure.

### DETAILED DESCRIPTION OF THE EMBODIMENTS

The present disclosure is described in further detail below with reference to the accompanying drawing and implementations. It can be understood that the specific implementations described herein are merely intended to explain the related content, rather than to limit the present disclosure. It should also be noted that, for convenience of description, only the parts related to the present disclosure are shown in the accompany drawings.

It should be noted that the implementations of the present disclosure or the features in the implementations may be combined with each other in a non-conflicting manner. The technical solutions of the present disclosure are described in detail below with reference to the accompanying drawing and implementations.

Unless otherwise stated, the exemplary implementations/embodiments shown are understood as providing exemplary features of various details of some manners for implementing technical concepts of the present disclosure in practice. Therefore, unless otherwise stated, without departing from the technical concepts of the present disclosure, features of various implementations/embodiments may be combined, separated, interchanged, and/or rearranged.

In the accompanying drawings, a crosshatch and/or shadow are/is usually used to make a boundary between adjacent components clear. Therefore, unless otherwise specified, the presence or absence of the crosshatch or shadow does not convey or represent any preference or requirement for specific materials, material properties, sizes, and proportions of components, a commonality of shown components, and/or any other characteristics, attributes, properties, and the like of the components. In addition, in the accompanying drawings, for clarity and/or descriptive purposes, the size and the relative size of the component can be exaggerated. When the exemplary embodiment can be implemented differently, a specific process sequence can be executed in an order different from the described order. For example, two consecutively described processes may be executed simultaneously or in a reverse order of the described order. In addition, the same reference numerals in the accompanying drawings represent the same parts.

When a component is described as being “on” or “above” another component, “being connected to”, or “being combined to” another component, the component may be directly on the another component, directly connected to or combined to the another component, or connected to the another component through an intermediate component. However, when a component is described as “being directly on”, “being directly connected to”, or “being directly combined to” another component, there is no intermediate component. For this purpose, the term “connection” may refer to a physical connection, an electrical connection, or the like, with or without an intermediate component.

For descriptive purposes, the present disclosure can use spatially relative terms, such as “below”, “below the lower side of”, “under”, “lower”, “on the upper side of”, “upper”, “above”, “higher”, and “side (such as in a “sidewall”)” to describe a relationship (relationships) between one component and another component (other components) as shown in the accompanying drawings. In addition to the orientations shown in the accompanying drawings, the spatially relative terms are intended to include different orientations of a device in use, operation, and/or manufacturing. For example, if the device in the accompanying drawing is turned upside down, a component described as being “below the lower side of” or “under” another component or feature is then located “above” the another component or feature. Therefore, the exemplary term “below the lower side of” may include orientations “above” and “below”. In addition, the device may be alternatively located (for example, rotated by 90 degrees or in another orientation), thus accordingly explaining spatially relative descriptors used herein.

The terms used herein are merely intended to describe specific embodiments, rather than to limit the present disclosure. As used herein, the singular forms “a”, “an” and “the” are intended to include the plural forms, unless the context clearly indicates otherwise. In addition, the terms “comprising”, “including”, and/or “containing” and variants thereof, when used in this specification, specify the presence of stated features, entireties, steps, operations, components, elements, and/or combinations thereof, but do not preclude the presence or addition of one or more other entireties, steps, operations, components, elements and/or combinations thereof. It should also be noted that the terms “basically”, “approximately”, and other similar terms used herein are used as approximate terms rather than degree terms, so that they are used to explain inherent deviations of measured values, calculated values, and/or provided values that are recognized by those of ordinary skill in the art.

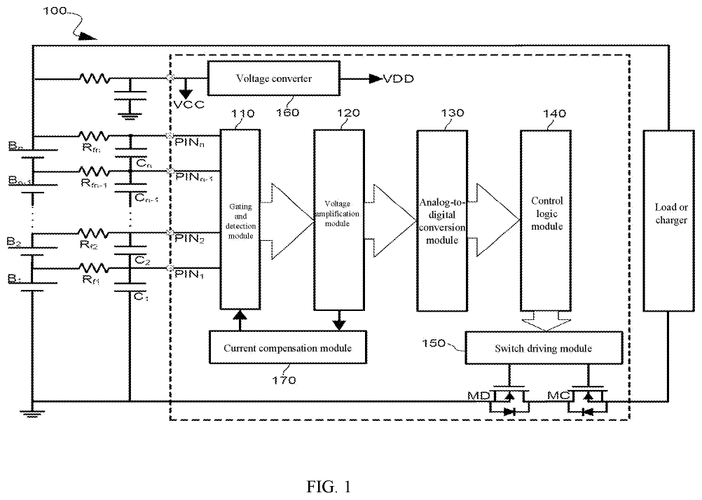

FIG. 1 is a schematic diagram of a battery management system according to an implementation of the present disclosure.

As shown in FIG. 1, the battery management system 100 can be configured to perform high-precision voltage collection and management on a battery. The battery may be a lithium battery pack, including a plurality of lithium batteries connected in series.

The battery management system 100 may include detection and gating module 110, voltage amplification module 120, analog-to-digital conversion module 130, control logic module 140, switch driving module 150, discharging switch MD, and charging switch MC.

The detection and gating module 110 gates and detects a voltage of each of batteries Bᵢ to Bₙ. The detection and gating module 110 may be configured to detect a battery voltage obtained after filtering. The filtering may be achieved by using a resistor-capacitor (RC) filter composed of filtering resistors Rn to Rfn and filtering capacitors C1 to Cn.

The voltage amplification module 120 can amplify the voltage of each battery from the detection and gating module 110.

The analog-to-digital conversion module 130 is configured to perform analog-to-digital conversion on the voltage of each battery from the voltage amplification module 120, and provide a converted digital signal for the control logic module 140.

The control logic module 140 can provide a control signal for the switch driving module 150 at least based on the detected battery voltage, so as to control the discharging switch MD and the charging switch MC by using the switch driving module 150, thus controlling charging and discharging of the battery. The battery is charged by an external charger, and is discharged by an external load of the battery management system.

In addition, the battery management system 100 may further include battery converter 160. The battery converter 160 is configured to convert highest battery voltage VCC of the battery into various required supply voltages VDDs. For example, the VDD may be 5 V.

As shown in FIG. 1, the battery management system 100 can obtain a voltage of a positive terminal of the first battery B₁ by using pin PIN₁, a voltage of a positive terminal of the second battery B₂ by using pin PIN₂, . . . , a voltage of a positive terminal of the (n−1)^{th} battery Bₙ₋₁ by using pin PINₙ₋₁, and a voltage of a positive terminal of the n^{th} battery Bₙ by using pin PINₙ.

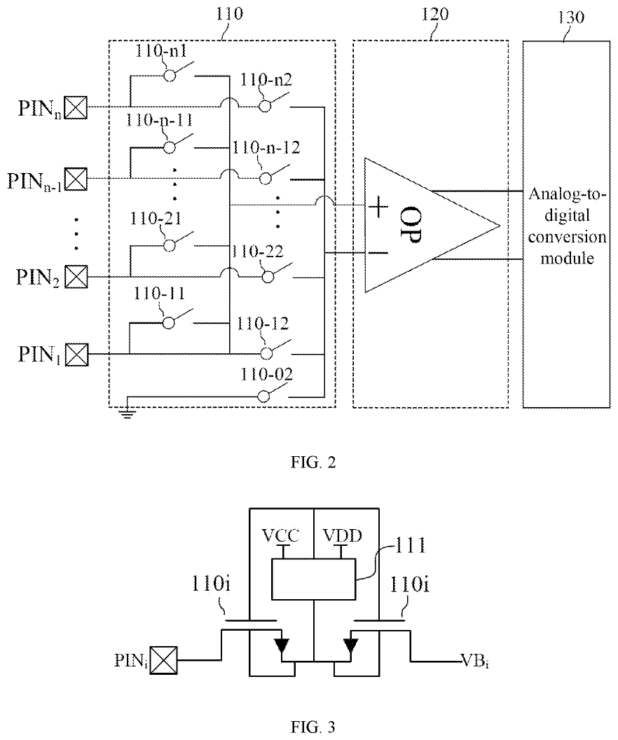

FIG. 2 is a schematic diagram of the detection and gating module 110 according to an implementation of the present disclosure. When a voltage of an i^{th} battery (1≤i≤n) is sampled, a switch connected to input pin PINᵢ of a voltage of a positive terminal of the i^{th} battery is turned on, and a switch connected to input pin PINᵢ₋₁ of a voltage of a negative terminal of the i^{th} battery (namely, an input pin of a voltage of a positive terminal of an (i−1)^{th} battery) is turned on. Two obtained voltages VPINᵢ and VPINᵢ₋₁ are respectively input into a positive input terminal (+) and a negative input terminal (−) of an operational amplifier (OP) of the voltage amplification module 120.

For example, when a voltage of the first battery B₁ is measured, switches 110-11 and 110-02 are turned on, such that two obtained voltages are respectively input into the positive input terminal (+) and the negative input terminal (−) of the OP. When a voltage of the second battery B₂ is measured, switches 110-21 and 110-12 are turned on, such that two obtained voltages are respectively input into the positive input terminal (+) and the negative input terminal (−) of the OP. When the voltage of the i^{th} battery B₁ is measured, switches 110-i1 and 110-i−12 are turned on, such that two obtained voltages are respectively input into the positive input terminal (+) and the negative input terminal (−) of the OP. When a voltage of the (n−1)^{th} battery Bₙ₋₁ is measured, switch 110-n−11 and 110-n−22 are turned on, such that two obtained voltages are respectively input into the positive input terminal (+) and the negative input terminal (−) of the OP. When a voltage of the n^{th} battery Bₙ is measured, switches 110-n1 and 110-n−12 are turned on, such that two obtained voltages are respectively input to the positive input terminal (+) and the negative input terminal (−) of the OP.

According to implementations of the present disclosure, a turn-on voltage generation circuit and a gate protection circuit are provided. As shown in FIG. 3, the turn-on voltage generation circuit and the gate protection circuit 111 apply a turn-on or turn-off voltage to gates of a first transistor and a second transistor (left transistor 110i and right transistor 110i), so as to turn on or off the first transistor and the second transistor. When the first transistor and the second transistor are turned on, voltage VBᵢ is equal to the voltage VPINᵢ. When the first transistor and the second transistor are turned off, no voltage sampling is performed.

The following embodiments are provided in the present disclosure to illustrate specific forms of the turn-on voltage generation circuit and the gate protection circuit.

The two transistors 110i shown in first to fifth embodiments below constitute an i^{th} switch (for example, switch 110-11) in the circuit shown in FIG. 3. A drain of the left transistor 110i receives the voltage VPINᵢ from the pin PINᵢ, and a source of the left transistor 110i is connected to a source of the right transistor 110i. When the two transistors are both turned on, a drain of the right transistor 110i outputs the battery voltage VBᵢ (equal to the VPINᵢ), and a gate of the left transistor 110i is connected to a gate of the right transistor 110i.

### First Embodiment

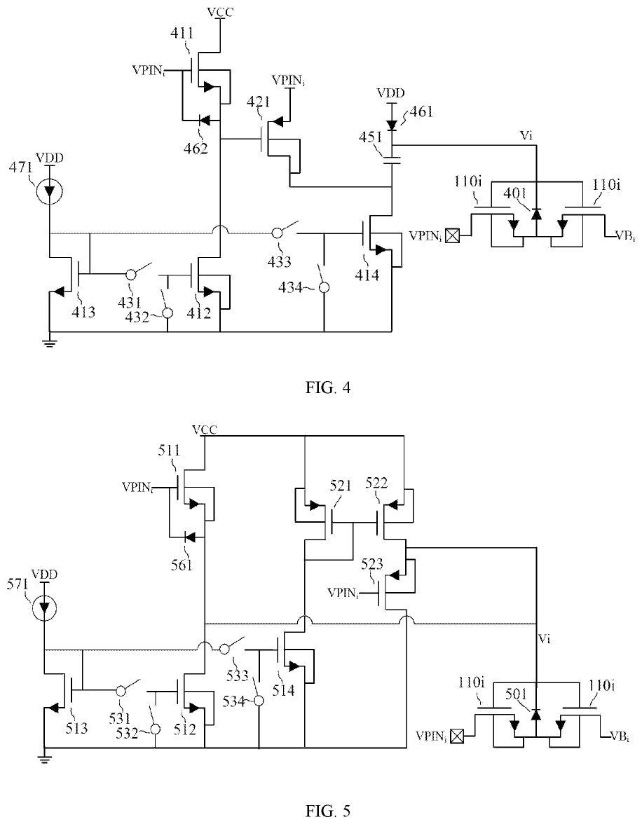

FIG. 4 shows a turn-on voltage generation circuit and a gate protection circuit according to the first embodiment of the present disclosure.

In this embodiment, protection diode 401 serves as the gate protection circuit. A cathode of the protection diode 401 is connected to a source of first transistor 110i (left transistor) and a source of second transistor 110i (right transistor), and an anode of the diode 401 is connected to a gate of the first transistor 110i and a gate of the second transistor 110i. Gate protection functions of the first transistor 110i and the second transistor 110i are achieved by using the diode 401.

In this embodiment, the turn-on voltage generation circuit is used to generate a voltage higher than battery voltage VPINᵢ of an i^{th} battery that is input by a drain of the first transistor by a predetermined voltage, to turn on the first transistor and the second transistor. In addition, the turn-on voltage generation circuit generates a voltage lower than the battery voltage VPINᵢ of the i^{th} battery that is input by the drain of the first transistor, to turn off the first transistor and the second transistor.

The turn-on voltage generation circuit is specifically set as follows:

A drain of first NMOS transistor 411 is connected to highest voltage VCC of a battery, a gate of the first NMOS transistor 411 is connected to the battery voltage VPINᵢ of the i^{th} battery, a source of the first NMOS transistor 411 is connected to a drain of second NMOS transistor 412, the source of the first NMOS transistor 411 is connected to a cathode of second diode 462, the gate of the first NMOS transistor 411 is connected to an anode of the second diode 462, a source of the second NMOS transistor 412 is grounded, a drain of third NMOS transistor 413 is connected to constant current source 471, the drain of the third NMOS transistor 413 is connected to a gate of the third NMOS transistor 413, the gate of the third NMOS transistor 413 is connected to one terminal of first switch 431, the other terminal of the first switch 431 is connected to a gate of the second NMOS transistor 412, the gate of the second NMOS transistor 412 is connected to one terminal of second switch 432, the other terminal of the second switch 432 is grounded, the drain of the third NMOS transistor 413 is connected to one terminal of third switch 433, the other terminal of the third switch 433 is connected to a gate of fourth NMOS transistor 414, a source of the fourth NMOS transistor 414 is grounded, the gate of the fourth NMOS transistor 414 is connected to one terminal of fourth switch 434, the other terminal of the fourth switch 434 is grounded, a gate of first PMOS transistor 421 is connected to the source of the first NMOS transistor 411, a source of the first PMOS transistor 421 is connected to the battery voltage VPINᵢ of the i^{th} battery, a drain of the first PMOS transistor 421 is connected to a drain of the fourth NMOS transistor 414, the drain of the fourth NMOS transistor 414 is connected to a bottom plate of capacitor 451, a top plate of the capacitor 451 is connected to an anode of first diode 461, a cathode of the first diode 461 is connected to supply voltage VDD, and the top plate of the capacitor 451 is connected to the anode of the protection diode 401. The turn-on voltage generation circuit is used to generate voltage Vi, so as to control turn-on and turn-off of the first transistor 110i and the second transistor 110i.

When the turn-on voltage Vi is higher than the battery voltage VPINᵢ of the i^{th} battery by the predetermined voltage, the first transistor and the second transistor are turned on. In this way, the output battery voltage VBᵢ is equal to the battery voltage VPINᵢ of the i^{th} battery. This is equivalent to that a gating switch in FIG. 3 is turned on.

Based on the turn-on voltage generation circuit in this embodiment, the first transistor and the second transistor can be stably turned on or off to avoid an error.

When the third switch 433 is turned on and the fourth switch 434 is turned off, the fourth NMOS transistor 414 is turned on. In this way, the bottom plate of the capacitor 451 is grounded, and a voltage of the top plate of the capacitor 451 is equal to the supply voltage VDD minus a voltage of the first diode 461. For example, when the supply voltage is 5 V and the voltage of the first diode 461 is 0.7 V, the voltage of the top plate of the capacitor 451 is 4.3 V. In this way, the voltage Vi is equal to 4.3 V, which is less than the battery voltage VPINᵢ of the i^{th} battery, such that the first transistor and the second transistor are not turned on.

When the third switch 433 is turned off and the fourth switch 434 is turned on, the fourth NMOS transistor 414 is turned off. In addition, when the first switch 431 is turned on and the second switch 432 is turned off, the second NMOS transistor 412 is turned on, such that a current of the first NMOS transistor 411 can flow through the second NMOS transistor 412. In this case, a voltage of the gate of the first PMOS transistor 421 is equal to the VPINᵢ minus a gate-source voltage of the first NMOS transistor 411, which is approximately equal to the battery voltage VPINᵢ of the i^{th} battery. In this way, after the first PMOS transistor 421 is turned on, a voltage of the bottom plate of the capacitor 451 is approximately equal to the battery voltage VPINᵢ of the i^{th} battery. Therefore, the voltage of the top plate of the capacitor 451 is equal to a voltage obtained by subtracting the voltage of the first diode 461 from a sum of the battery voltage VPINᵢ of the i^{th} battery and the supply voltage VDD, such that the voltage Vi is also equal to this voltage, making the Vi higher than the battery voltage VPINᵢ of the i^{th} battery by the predetermined voltage. In this way, the first transistor and the second transistor are turned on, such that the battery voltage VPINᵢ of the i^{th} battery can be collected and the output voltage VBᵢ is equal to the battery voltage VPINᵢ of the i^{th} battery.

### Second Embodiment

FIG. 5 shows a turn-on voltage generation circuit and a gate protection circuit according to the second embodiment of the present disclosure.

In this embodiment, protection diode 501 serves as the gate protection circuit. A cathode of the protection diode 501 is connected to a source of first transistor 110i (left transistor) and a source of second transistor 110i (right transistor), and an anode of the protection diode 501 is connected to a gate of the first transistor 110i and a gate of the second transistor 110i. Gate protection functions of the first transistor 110i and the second transistor 110i are achieved by using the diode 501.

In this embodiment, the turn-on voltage generation circuit is used to generate a voltage higher than battery voltage VPINᵢ of an i^{th} battery that is input by a drain of the first transistor by a predetermined voltage, to turn on the first transistor and the second transistor. In addition, the turn-on voltage generation circuit generates a voltage lower than the battery voltage VPINᵢ of the i^{th} battery that is input by the drain of the first transistor, to turn off the first transistor and the second transistor.

The turn-on voltage generation circuit is specifically set as follows:

A drain of first NMOS transistor 511 is connected to highest voltage VCC of a battery, a gate of the first NMOS transistor 511 is connected to the battery voltage VPINᵢ of the i^{th} battery, a source of the first NMOS transistor 511 is connected to a cathode of a first diode 561, the gate of the first NMOS transistor 511 is connected to an anode of the first diode 561, the source of the first NMOS transistor 511 is connected to a drain of second NMOS transistor 512, a source of the second NMOS transistor 512 is grounded, a drain of third NMOS transistor 513 is connected to constant current source 571, the drain of the third NMOS transistor 513 is connected to a gate of the third NMOS transistor 513, the gate of the third NMOS transistor 513 is connected to one terminal of first switch 531, the other terminal of the first switch 531 is connected to a gate of the second NMOS transistor 512, the gate of the second NMOS transistor 512 is connected to one terminal of second switch 532, the other terminal of the second switch 532 is grounded, the drain of the third NMOS transistor 513 is connected to one terminal of third switch 533, the other terminal of the third switch 533 is connected to a gate of fourth NMOS transistor 514, a source of the fourth NMOS transistor 514 is grounded, the gate of the fourth NMOS transistor 514 is connected to one terminal of fourth switch 534, the other terminal of the fourth switch 534 is grounded, a gate of first PMOS transistor 521 is connected to a gate of second PMOS transistor 522, the gate of the first PMOS transistor 521 is connected to a drain of the first PMOS transistor 521, a source of the first PMOS transistor 521 and a source of the second PMOS transistor 522 are connected to the highest voltage of the battery, the drain of the first PMOS transistor 521 is connected to a drain of the fourth NMOS transistor 514, a drain of the second PMOS transistor 522 is connected to a source of third PMOS transistor 523, a gate of the third PMOS transistor 523 is connected to the battery voltage VPINᵢ of the i^{th} battery, a drain of the third PMOS transistor 523 is grounded, the drain of the second NMOS transistor 512 is connected to the anode of the protection diode 501, and the source of the third PMOS transistor 523 is connected to the anode of the protection diode 501. The turn-on voltage generation circuit is used to generate voltage Vi, so as to control turn-on and turn-off of the first transistor 110i and the second transistor 110i.

When the turn-on voltage Vi is higher than the battery voltage VPINᵢ of the i^{th} battery by the predetermined voltage, the first transistor and the second transistor are turned on. In this way, the output battery voltage VBᵢ is equal to the battery voltage VPINᵢ of the i^{th} battery. This is equivalent to that a gating switch in FIG. 3 is turned on.

Based on the turn-on voltage generation circuit in this embodiment, the first transistor and the second transistor can be stably turned on or off to avoid an error.

A principle of FIG. 5 is the same as that of FIG. 4. In FIG. 5, the first switch to the fourth switch are controlled to generate the voltage Vi higher than the battery voltage VPINᵢ of the i^{th} battery by the predetermined voltage, to turn on the first transistor and the second transistor, or generate the voltage Vi lower than the battery voltage VPINᵢ of the i^{th} battery, to turn off the first transistor and the second transistor.

### Third Embodiment

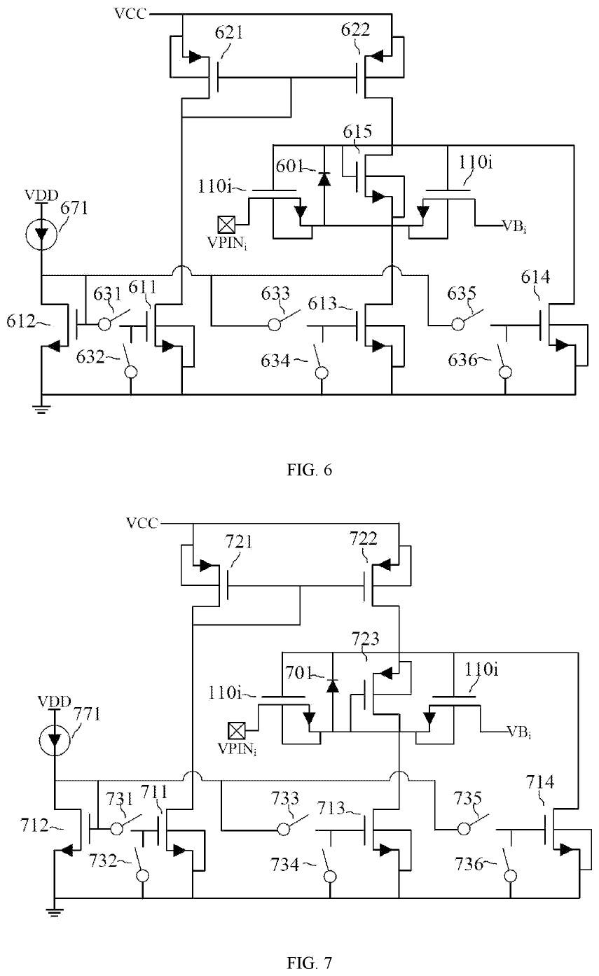

FIG. 6 shows a turn-on voltage generation circuit and a gate protection circuit according to the third embodiment of the present disclosure.

In this embodiment, protection diode 601 serves as the gate protection circuit. A cathode of the protection diode 601 is connected to a source of first transistor 110i (left transistor) and a source of second transistor 110i (right transistor), and an anode of the protection diode 601 is connected to a gate of the first transistor 110i and a gate of the second transistor 110i. Gate protection functions of the first transistor 110i and the second transistor 110i are achieved by using the diode 601.

In this embodiment, the turn-on voltage generation circuit is used to generate a voltage higher than battery voltage VPINᵢ of an i^{th} battery that is input by a drain of the first transistor by a predetermined voltage, to turn on the first transistor and the second transistor. In addition, the turn-on voltage generation circuit generates a voltage lower than the battery voltage VPINᵢ of the i^{th} battery that is input by the drain of the first transistor, to turn off the first transistor and the second transistor.

In this embodiment, the turn-on voltage generation circuit is specifically set as follows: A source of first PMOS transistor 621 and a source of second PMOS transistor 622 are connected to highest voltage VCC of a battery, a gate of the first PMOS transistor 621 is connected to a drain of the first PMOS transistor 621, the gate of the first PMOS transistor 621 is connected to a gate of the second PMOS transistor 622 to form a mirror circuit, the drain of the first PMOS transistor 621 is connected to a drain of first NMOS transistor 611, a source of the first NMOS transistor 611 is grounded, a drain of second NMOS transistor 612 is connected to constant current source 671, the drain of the second NMOS transistor 612 is connected to a gate of the second NMOS transistor 612, a source of the second NMOS transistor 612 is grounded, the gate of the second NMOS transistor 612 is connected to one terminal of first switch 631, the other terminal of the first switch 631 is connected to a gate of the first NMOS transistor 611, one terminal of second switch 632 is connected to the gate of the first NMOS transistor 611, the other terminal of the second switch 632 is grounded, the drain of the second NMOS transistor 612 is connected to one terminal of third switch 633, the other terminal of the third switch 633 is connected to a gate of third NMOS transistor 613, one terminal of fourth switch 634 is connected to the gate of the third NMOS transistor 613, the other terminal of the fourth switch 634 is grounded, the drain of the second NMOS transistor 612 is connected to one terminal of fifth switch 635, the other terminal of the fifth switch 635 is connected to a gate of fourth NMOS transistor 614, one terminal of sixth switch 636 is connected to the gate of the fourth NMOS transistor 614, the other terminal of the sixth switch 636 is grounded, a drain of the third NMOS transistor 613 is connected to a source of fifth NMOS transistor 615 and to the sources of the first transistor and the second transistor, a drain of the fourth NMOS transistor 614 is connected to a drain of the fifth NMOS transistor 615 and to the gates of the first transistor and the second transistor, a drain of the second PMOS transistor 622 is connected to the drain of the fifth NMOS transistor 615, and a gate of the fifth NMOS transistor 615 is connected to the drain of the fifth NMOS transistor 615.

The turn-on voltage generation circuit is used to generate voltage Vi, so as to control turn-on and turn-off of the first transistor 110i and the second transistor 110i.

When the turn-on voltage Vi is higher than the battery voltage VPINᵢ of the i^{th} battery by the predetermined voltage, the first transistor and the second transistor are turned on. In this way, the output battery voltage VBᵢ is equal to the battery voltage VPINᵢ of the i^{th} battery. This is equivalent to that a gating switch in FIG. 3 is turned on.

Based on the turn-on voltage generation circuit in this embodiment, the first transistor and the second transistor can be stably turned on or off to avoid an error.

In this embodiment, when the first switch 631 and the third switch 633 are turned on, and the fifth switch 635 is turned off, the first NMOS transistor 611 is turned on, and the third NMOS transistor 613 is turned on. In this way, a current is formed in the first PMOS transistor and a branch of the first NMOS transistor 611. Due to the mirror circuit, the same current is also formed in branches of the third NMOS transistor 613, the fifth NMOS transistor 615, and the second PMOS transistor 622 that are turned on. In this way, a gate-source voltage of the fifth NMOS transistor 615 is equal to gate-source voltages of the first transistor 110i and the second transistor 110i, such that the first transistor 110i and the second transistor 110i are turned on, and the voltage VBᵢ is equal to the battery voltage VPINᵢ of the battery.

When the first switch 631 and the third switch 633 are turned off, and the fifth switch 635 is turned on, the first NMOS transistor 611 is turned off, the third NMOS transistor 613 is turned off, and the fifth NMOS transistor 615 is turned off, with no current flowing through. In addition, because the fifth switch 635 is turned on, the fourth NMOS transistor 614 is turned on, which makes voltages of the gates of the first transistor 110i and the second transistor 110i approximately equal to zero. As a result, the first transistor 110i and the second transistor 110i are turned off, which plays a role of turning off the switch in FIG. 3.

### Fourth Embodiment

FIG. 7 shows a turn-on voltage generation circuit and a gate protection circuit according to the fourth embodiment of the present disclosure.

In this embodiment, protection diode 701 serves as the gate protection circuit. A cathode of the protection diode 701 is connected to a source of first transistor 110i (left transistor) and a source of second transistor 110i (right transistor), and an anode of the protection diode 701 is connected to a gate of the first transistor 110i and a gate of the second transistor 110i. Gate protection functions of the first transistor 110i and the second transistor 110i are achieved by using the diode 701.

In this embodiment, the turn-on voltage generation circuit is used to generate a turn-on voltage for turning on the first transistor and the second transistor. In addition, the turn-on voltage generation circuit generates a turn-off voltage for turning off a drain of the first transistor, to turn off the first transistor and the second transistor.

In this embodiment, the turn-on voltage generation circuit is specifically set as follows: A source of first PMOS transistor 721 and a source of second PMOS transistor 722 are connected to highest voltage VCC of a battery, a gate of the first PMOS transistor 721 is connected to a drain of the first PMOS transistor 721, the gate of the first PMOS transistor 721 is connected to a gate of the second PMOS transistor 722 to form a mirror circuit, the drain of the first PMOS transistor 721 is connected to a drain of first NMOS transistor 711, a source of the first NMOS transistor 711 is grounded, a drain of second NMOS transistor 712 is connected to constant current source 771, the drain of the second NMOS transistor 712 is connected to a gate of the second NMOS transistor 712, a source of the second NMOS transistor 712 is grounded, the gate of the second NMOS transistor 712 is connected to one terminal of first switch 731, the other terminal of the first switch 731 is connected to a gate of the first NMOS transistor 711, one terminal of second switch 732 is connected to the gate of the first NMOS transistor 711, the other terminal of the second switch 732 is grounded, the drain of the second NMOS transistor 712 is connected to one terminal of third switch 733, the other terminal of the third switch 733 is connected to a gate of third NMOS transistor 713, one terminal of fourth switch 734 is connected to the gate of the third NMOS transistor 713, the other terminal of the fourth switch 734 is grounded, the drain of the second NMOS transistor 712 is connected to one terminal of fifth switch 735, the other terminal of the fifth switch 735 is connected to a gate of fourth NMOS transistor 714, one terminal of sixth switch 736 is connected to the gate of the fourth NMOS transistor 714, the other terminal of the sixth switch 736 is grounded, a drain of the third NMOS transistor 713 is connected to a drain of third PMOS transistor 723 and to the sources of the first transistor and the second transistor, a drain of the fourth NMOS transistor 714 is connected to a source of the third PMOS transistor 723 and to the gates of the first transistor and the second transistor, a drain of the second PMOS transistor 722 is connected to the source of the third PMOS transistor 723, and a gate of the third PMOS transistor 723 is connected to the drain of the third PMOS transistor 723.

The turn-on voltage generation circuit is used to generate voltage Vi, so as to control turn-on and turn-off of the first transistor 110i and the second transistor 110i.

Based on the turn-on voltage generation circuit in this embodiment, the first transistor and the second transistor can be stably turned on or off to avoid an error.

In this embodiment, when the first switch 731 and the third switch 733 are turned on, and the fifth switch 735 is turned off, the first NMOS transistor 711 is turned on, and the third NMOS transistor 713 is turned on. In this way, a current is formed in the first PMOS transistor and a branch of the first NMOS transistor 711. Due to the mirror circuit, the same current is also formed in branches of the third NOMOS transistor 713, the third PMOS transistor 723, and the second PMOS transistor 722 that are turned on. In this way, a gate-source voltage of the third PMOS transistor 723 is equal to gate-source voltages of the first transistor 110i and the second transistor 110i, such that the first transistor 110i and the second transistor 110i are turned on, and voltage VBᵢ is equal to battery voltage VPINᵢ of an i^{th} battery.

When the first switch 731 and the third switch 733 are turned off, and the fifth switch 735 is turned on, the first NMOS transistor 711 is turned off, the third NMOS transistor 713 is turned off, and the third PMOS transistor 723 is turned off, with no current flowing through. In addition, because the fifth switch 735 is turned on, the fourth NMOS transistor 714 is turned on, which makes voltages of the gates of the first transistor 110i and the second transistor 110i approximately equal to zero. As a result, the first and the second transistors 110i are turned off, which plays a role of turning off the switch in FIG. 3.

### Fifth Embodiment

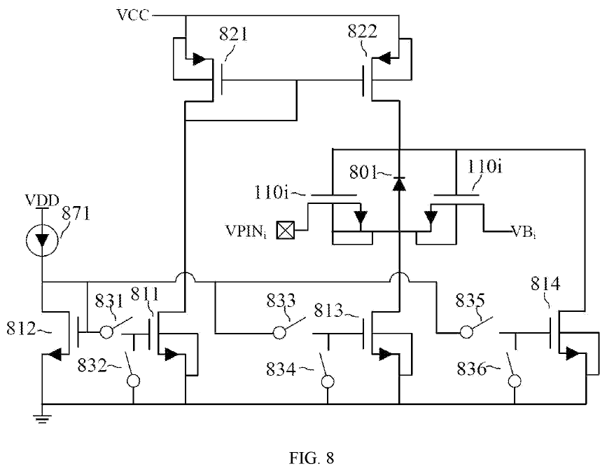

FIG. 8 shows a turn-on voltage generation circuit and a gate protection circuit according to the fifth embodiment of the present disclosure.

In this embodiment, protection diode 801 serves as the gate protection circuit. A cathode of the protection diode 801 is connected to a source of first transistor 110i (left transistor) and a source of second transistor 110i (right transistor), and an anode of the protection diode 801 is connected to a gate of the first transistor 110i and a gate of the second transistor 110i. Gate protection functions of the first transistor 110i and the second transistor 110i are achieved by using the diode 801.

In this embodiment, the turn-on voltage generation circuit is used to generate a turn-on voltage for turning on the first transistor and the second transistor. In addition, the turn-on voltage generation circuit generates a turn-off voltage for turning off a drain of the first transistor, to turn off the first transistor and the second transistor.

In this embodiment, the turn-on voltage generation circuit is specifically set as follows: A source of first PMOS transistor 821 and a source of second PMOS transistor 822 are connected to highest voltage VCC of a battery, a gate of the first PMOS transistor 821 is connected to a drain of the first PMOS transistor 821, the gate of the first PMOS transistor 821 is connected to a gate of the second PMOS transistor 822 to form a mirror circuit, the drain of the first PMOS transistor 821 is connected to a drain of first NMOS transistor 811, a source of the first NMOS transistor 811 is grounded, a drain of second NMOS transistor 812 is connected to constant current source 871, the drain of the second NMOS transistor 812 is connected to a gate of the second NMOS transistor 812, a source of the second NMOS transistor 812 is grounded, the gate of the second NMOS transistor 812 is connected to one terminal of first switch 831, the other terminal of the first switch 831 is connected to a gate of the first NMOS transistor 811, one terminal of second switch 832 is connected to the gate of the first NMOS transistor 811, the other terminal of the second switch 832 is grounded, the drain of the second NMOS transistor 812 is connected to one terminal of third switch 833, the other terminal of the third switch 833 is connected to a gate of third NMOS transistor 813, one terminal of fourth switch 834 is connected to the gate of the third NMOS transistor 813, the other terminal of the fourth switch 834 is grounded, the drain of the second NMOS transistor 812 is connected to one terminal of fifth switch 835, the other terminal of the fifth switch 835 is connected to a gate of fourth NMOS transistor 814, one terminal of sixth switch 836 is connected to the gate of the fourth NMOS transistor 814, the other terminal of the sixth switch 836 is grounded, a drain of the third NMOS transistor 813 is connected to the sources of the first transistor and the second transistor, a drain of the fourth NMOS transistor 814 is connected to the gates of the first transistor and the second transistor, and a drain of the second PMOS transistor 822 is connected to the gates of the first transistor and the second transistor.

The turn-on voltage generation circuit is used to generate voltage Vi, so as to control turn-on and turn-off of the first transistor 110i and the second transistor 110i.

Based on the turn-on voltage generation circuit in this embodiment, the first transistor and the second transistor can be stably turned on or off to avoid an error.

In this embodiment, when the first switch 831 and the third switch 833 are turned on, and the fifth switch 835 is turned off, the first NMOS transistor 811 is turned on, and the third NMOS transistor 813 is turned on. In this way, a current is formed in the first PMOS transistor and a branch of the first NMOS transistor 811. Due to the mirror circuit, the same current is also formed in branches of the third NOMOS transistor 813, the protection diode 801, and the second PMOS transistor 822 that are turned on. As a result, reverse breakdown occurs, and a breakdown voltage is generated. The breakdown voltage is equal to gate-source voltages of the first transistor 110i and the second transistor 110i, such that the first transistor 110i and the second transistor 110i are turned on, and voltage VBᵢ is equal to battery voltage VPINᵢ of an i^{th} battery.

When the first switch 831 and the third switch 833 are turned off, and the fifth switch 835 is turned on, the first NMOS transistor 811 is turned off, and the third NMOS transistor 813 is turned off. In addition, because the fifth switch 835 is turned on, the fourth NMOS transistor 814 is turned on, and a forward current flows through the protection diode 801. In this way, voltages of the gates of the first transistor 110i and the second transistor 110i are very small, failing to form a sufficiently large turn-on voltage. As a result, the first transistor 110i and the second transistor 110i are turned off, which plays a role of turning off the switch in FIG. 3.

To sum up, the present disclosure provides at least following technical solutions.

Technical solution 1: A detection and gating module in a battery management system is provided. The detection and gating module is configured to detect a voltage of each battery in a battery pack containing N batteries connected in series, where N≥1. The detection and gating module includes: N gating switches, where an i^{th} gating switch of the N gating switches is connected to a positive terminal of an i^{th} battery of the N batteries, a voltage of the i^{th} battery is detected when the i^{th} gating switch is turned on, and 1≤1≤N; N protection circuits, where an i^{th} protection circuit of the N protection circuits is configured to protect the i^{th} gating switch of the N gating switches; and N voltage generation circuits, where an i^{th} voltage generation circuit of the N voltage generation circuits is configured to generate a turn-on voltage for turning on the i^{th} gating switch of the N gating switches and a turn-off voltage for turning off the i^{th} gating switch.

Technical solution 2: According to the detection and gating module described in the technical solution 1, when the voltage of the i^{th} battery is detected, battery voltages at both ends of the i^{th} battery are detected by turning on the i^{th} gating switch and an (i−1)^{th} gating switch.

Technical solution 3: According to the detection and gating module described in the technical solution 2, the i^{th} gating switch includes a first transistor and a second transistor, a drain of the first transistor is connected to a battery voltage at the positive terminal of the i^{th} battery, a source of the first transistor is connected to a source of the second transistor, a gate of the first transistor is connected to a gate of the second transistor, and a drain of the second transistor outputs a sampled battery voltage.

Technical solution 4: According to the detection and gating module described in the technical solution 3, the i^{th} protection circuit is a protection diode, a cathode of the i^{th} protection diode is connected to the sources of the first transistor and the second transistor of the i^{th} gating switch, and an anode of the i^{th} protection diode is connected to the gates of the first transistor and the second transistor of the i^{th} gating switch.

Technical solution 5: According to the detection and gating module described in the technical solution 4,
when the voltage of the i^{th} battery is detected, a control voltage higher than the battery voltage at the positive terminal of the i^{th} battery by a predetermined voltage is generated by the i^{th} voltage generation circuit to turn on the first transistor and the second transistor of the i^{th} gating switch, and a control voltage higher than a battery voltage at a positive terminal of an (i−1)^{th} battery by the predetermined voltage is generated by an (i−1)^{th} voltage generation circuit to turn on a first transistor and a second transistor of the (i−1)^{th} gating switch; and
when the voltage of the i^{th} battery is not detected, a control voltage lower than the battery voltage at the positive terminal of the i^{th} battery is generated by the i^{th} voltage generation circuit to turn off the first transistor and the second transistor of the i^{th} gating switch, and a control voltage lower than the battery voltage at the positive terminal of the (i−1)^{th} battery is generated by the (i−1)^{th} voltage generation circuit to turn off the first transistor and the second transistor of the (i−1)^{th} gating switch.

Technical solution 6: According to the detection and gating module described in the technical solution 4,
when the voltage of the i^{th} battery is detected, a turn-on voltage for turning on the first transistor and the second transistor of the i^{th} gating switch is generated by the i^{th} voltage generation circuit, and a turn-on voltage for turning on a first transistor and a second transistor of the (i−1)^{th} gating switch is generated by an (i−1)^{th} voltage generation circuit; and
when the voltage of the i^{th} battery is not detected, a turn-off voltage for turning off the first transistor and the second transistor of the i^{th} gating switch is generated by the i^{th} voltage generation circuit, and a turn-off voltage for turning off the first transistor and the second transistor of the (i−1)^{th} gating switch is generated by the (i−1)^{th} voltage generation circuit.

Technical solution 7: According to the detection and gating module described in the technical solution 5, the i^{th} voltage generation circuit includes a capacitor, the control voltage is provided by charging and discharging of the capacitor, to turn on or off the first transistor and the second transistor of the i^{th} gating switch.

Technical solution 8: According to the detection and gating module described in the technical solution 7, the i^{th} voltage generation circuit includes:
a drain of a first NMOS transistor is connected to a highest voltage of the battery pack, a gate of the first NMOS transistor is connected to the battery voltage at the positive terminal of the i^{th} battery, a source of the first NMOS transistor is connected to a drain of a second NMOS transistor, the source of the first NMOS transistor is connected to a cathode of a second diode, the gate of the first NMOS transistor is connected to an anode of the second diode, a source of the second NMOS transistor is grounded, a drain of a third NMOS transistor is connected to a constant current source, the drain of the third NMOS transistor is connected to a gate of the third NMOS transistor, the gate of the third NMOS transistor is connected to one terminal of a first switch, the other terminal of the first switch is connected to a gate of the second NMOS transistor, the gate of the second NMOS transistor is connected to one terminal of a second switch, the other terminal of the second switch is grounded, the drain of the third NMOS transistor is connected to one terminal of a third switch, the other terminal of the third switch is connected to a gate of a fourth NMOS transistor, a source of the fourth NMOS transistor is grounded, the gate of the fourth NMOS transistor is connected to one terminal of a fourth switch, the other terminal of the fourth switch is grounded, a gate of a first PMOS transistor is connected to the source of the first NMOS transistor, a source of the first PMOS transistor is connected to the battery voltage at the positive terminal of the i^{th} battery, a drain of the first PMOS transistor is connected to a drain of the fourth NMOS transistor, the drain of the fourth NMOS transistor is connected to a bottom plate of the capacitor, a top plate of the capacitor is connected to an anode of a first diode, a cathode of the first diode is connected to a supply voltage, and the top plate of the capacitor is connected to the anode of the protection diode.

Technical solution 9: According to the detection and gating module described in the technical solution 5, the i^{th} voltage generation circuit includes:
a drain of a first NMOS transistor is connected to a highest voltage of the battery pack, a gate of the first NMOS transistor is connected to the battery voltage at the positive terminal of the i^{th} battery, a source of the first NMOS transistor is connected to a cathode of a first diode, the gate of the first NMOS transistor is connected to an anode of the first diode, the source of the first NMOS transistor is connected to a drain of a second NMOS transistor, a source of the second NMOS transistor is grounded, a drain of a third NMOS transistor is connected to a constant current source, the drain of the third NMOS transistor is connected to a gate of the third NMOS transistor, the gate of the third NMOS transistor is connected to one terminal of a first switch, the other terminal of the first switch is connected to a gate of the second NMOS transistor, the gate of the second NMOS transistor is connected to one terminal of a second switch, the other terminal of the second switch is grounded, the drain of the third NMOS transistor is connected to one terminal of a third switch, the other terminal of the third switch is connected to a gate of a fourth NMOS transistor, a source of the fourth NMOS transistor is grounded, the gate of the fourth NMOS transistor is connected to one terminal of a fourth switch, the other terminal of the fourth switch is grounded, a gate of a first PMOS transistor is connected to a gate of a second PMOS transistor, the gate of the first PMOS transistor is connected to a drain of the first PMOS transistor, a source of the first PMOS transistor and a source of the second PMOS transistor are connected to the highest voltage of the battery pack, the drain of the first PMOS transistor is connected to a drain of the fourth NMOS transistor, a drain of the second PMOS transistor is connected to a source of a third PMOS transistor, a gate of the third PMOS transistor is connected to the battery voltage at the positive terminal of the i^{th} battery, a drain of the third PMOS transistor is grounded, the drain of the second NMOS transistor is connected to the anode of the protection diode, and the source of the third PMOS transistor is connected to the anode of the protection diode.

Technical solution 10: According to the detection and gating module described in the technical solution 6, the i^{th} voltage generation circuit includes a fifth NMOS transistor, a drain of the fifth NMOS transistor is connected to the gates of the first transistor and the second transistor, a source of the fifth NMOS transistor is connected to the sources of the first transistor and the second transistor, and a gate of the fifth NMOS transistor is connected to the drain of the fifth NMOS transistor to provide the control voltage through turn-on or turn-off of the fifth NMOS transistor, so as to turn on or off the first transistor and the second transistor of the i^{th} gating switch.

Technical solution 11: According to the detection and gating module described in the technical solution 10, the i^{th} voltage generation circuit includes:
a source of a first PMOS transistor and a source of a second PMOS transistor are connected to a highest voltage of the battery pack, a gate of the first PMOS transistor is connected to a drain of the first PMOS transistor, the gate of the first PMOS transistor is connected to a gate of the second PMOS transistor to form a mirror circuit, the drain of the first PMOS transistor is connected to a drain of a first NMOS transistor, a source of the first NMOS transistor is grounded, a drain of a second NMOS transistor is connected to a constant current source, the drain of the second NMOS transistor is connected to a gate of the second NMOS transistor, a source of the second NMOS transistor is grounded, the gate of the second NMOS transistor is connected to one terminal of a first switch, the other terminal of the first switch is connected to a gate of the first NMOS transistor, one terminal of a second switch is connected to the gate of the first NMOS transistor, the other terminal of the second switch is grounded, the drain of the second NMOS transistor is connected to one terminal of a third switch, the other terminal of the third switch is connected to a gate of a third NMOS transistor, one terminal of a fourth switch is connected to the gate of the third NMOS transistor, the other terminal of the fourth switch is grounded, the drain of the second NMOS transistor is connected to one terminal of a fifth switch, the other terminal of the fifth switch is connected to a gate of a fourth NMOS transistor, one terminal of a sixth switch is connected to the gate of the fourth NMOS transistor, the other terminal of the sixth switch is grounded, a drain of the third NMOS transistor is connected to the source of the fifth NMOS transistor and to the sources of the first transistor and the second transistor, a drain of the fourth NMOS transistor is connected to the drain of the fifth NMOS transistor and to the gates of the first transistor and the second transistor, a drain of the second PMOS transistor is connected to the drain of the fifth NMOS transistor, and the gate of the fifth NMOS transistor is connected to the drain of the fifth NMOS transistor.

Technical solution 12: According to the detection and gating module described in the technical solution 6, the it h voltage generation circuit includes a third PMOS transistor, a source of the third PMOS transistor is connected to the gates of the first transistor and the second transistor, a drain of the third PMOS transistor is connected to the sources of the first transistor and the second transistor, and a gate of the third PMOS transistor is connected to the drain of the third PMOS transistor to provide the control voltage through turn-on or turn-off of the third PMOS transistor, so as to turn on or off the first transistor and the second transistor of the i^{th} gating switch.

Technical solution 13: According to the detection and gating module described in the technical solution 12, the i^{th} voltage generation circuit includes:
a source of a first PMOS transistor and a source of a second PMOS transistor are connected to a highest voltage of the battery pack, a gate of the first PMOS transistor is connected to a drain of the first PMOS transistor, the gate of the first PMOS transistor is connected to a gate of the second PMOS transistor to form a mirror circuit, the drain of the first PMOS transistor is connected to a drain of a first NMOS transistor, a source of the first NMOS transistor is grounded, a drain of a second NMOS transistor is connected to a constant current source, the drain of the second NMOS transistor is connected to a gate of the second NMOS transistor, a source of the second NMOS transistor is grounded, the gate of the second NMOS transistor is connected to one terminal of a first switch, the other terminal of the first switch is connected to a gate of the first NMOS transistor, one terminal of a second switch is connected to the gate of the first NMOS transistor, the other terminal of the second switch is grounded, the drain of the second NMOS transistor is connected to one terminal of a third switch, the other terminal of the third switch is connected to a gate of a third NMOS transistor, one terminal of a fourth switch is connected to the gate of the third NMOS transistor, the other terminal of the fourth switch is grounded, the drain of the second NMOS transistor is connected to one terminal of a fifth switch, the other terminal of the fifth switch is connected to a gate of a fourth NMOS transistor, one terminal of a sixth switch is connected to the gate of the fourth NMOS transistor, the other terminal of the sixth switch is grounded, a drain of the third NMOS transistor is connected to the drain of the third PMOS transistor and to the sources of the first transistor and the second transistor, a drain of the fourth NMOS transistor is connected to the source of the third PMOS transistor and to the gates of the first transistor and the second transistor, a drain of the second PMOS transistor is connected to the source of the third PMOS transistor, and the gate of the third PMOS transistor is connected to the drain of the third PMOS transistor.

Technical solution 14: According to the detection and gating module described in the technical solution 6, the i^{th} voltage generation circuit is the protection diode, and the control voltage is provided by using a reverse breakdown voltage when the protection diode is broken down reversely, to turn on or off the first transistor and the second transistor of the i^{th} gating switch.

Technical solution 15: According to the detection and gating module described in the technical solution 14, the i^{th} voltage generation circuit includes:
a source of a first PMOS transistor and a source of a second PMOS transistor are connected to a highest voltage of the battery pack, a gate of the first PMOS transistor is connected to a drain of the first PMOS transistor, the gate of the first PMOS transistor is connected to a gate of the second PMOS transistor to form a mirror circuit, the drain of the first PMOS transistor is connected to a drain of a first NMOS transistor, a source of the first NMOS transistor is grounded, a drain of a second NMOS transistor is connected to a constant current source, the drain of the second NMOS transistor is connected to a gate of the second NMOS transistor, a source of the second NMOS transistor is grounded, the gate of the second NMOS transistor is connected to one terminal of a first switch, the other terminal of the first switch is connected to a gate of the first NMOS transistor, one terminal of a second switch is connected to the gate of the first NMOS transistor, the other terminal of the second switch is grounded, the drain of the second NMOS transistor is connected to one terminal of a third switch, the other terminal of the third switch is connected to a gate of a third NMOS transistor, one terminal of a fourth switch is connected to the gate of the third NMOS transistor, the other terminal of the fourth switch is grounded, the drain of the second NMOS transistor is connected to one terminal of a fifth switch, the other terminal of the fifth switch is connected to a gate of a fourth NMOS transistor, one terminal of a sixth switch is connected to the gate of the fourth NMOS transistor, the other terminal of the sixth switch is grounded, a drain of the third NMOS transistor is connected to the sources of the first transistor and the second transistor, a drain of the fourth NMOS transistor is connected to the gates of the first transistor and the second transistor, and a drain of the second PMOS transistor is connected to the gates of the first transistor and the second transistor.

Technical solution 16: A battery management system includes:
the detection and gating module according to any one of the technical solutions 1 to 15, where the detection and gating module is configured to detect a voltage of each battery in a battery pack containing N batteries connected in series; and
a voltage amplification module configured to receive the voltage of each battery that is output by the detection and gating module, to amplify and output the voltage of each battery.

Technical solution 17: The battery management system described in the technical solution 16 further includes:
an analog-to-digital conversion module configured to perform analog-to-digital conversion on the voltage of each battery from the voltage amplification module; and
a control logic module configured to receive a battery voltage converted by the analog-to-digital conversion module, and provide a control signal for a switch driving module at least based on the converted battery voltage, so as to control turn-on or turn-off of a discharging switch and a charging switch by using the switch driving module.

Technical solution 18: A battery management chip is provided, which is integrated with the battery management system according to the technical solution 16 or 17.

In the description of this specification, the description of the terms “one embodiment/implementation”, “some embodiments/implementations”, “example”, “specific example”, or “some examples” means that the specific features, structures, materials, or characteristics described with reference to the embodiment/implementation or example are included in at least one embodiment/implementation or example of the present disclosure. In this specification, the illustrative expressions of the above terms are not intended to refer to the same embodiment/implementation or example. Moreover, the specific features, structures, materials, or characteristics described may be combined in any suitable manner in any one or more embodiments/implementations or examples. In addition, those skilled in the art may combine different embodiments/implementations or examples described herein or features in different embodiments/implementations or examples without any contradiction.

In addition, the terms “first” and “second” are merely intended for a purpose of description, and shall not be understood as an indication or implication of relative importance or implicit indication of a quantity of indicated technical features. Therefore, a feature limited by “first” or “second” may explicitly or implicitly include at least one such feature. In the description of the present disclosure, “a plurality of” means at least two, such as two or three, unless otherwise clearly and specifically limited.

Those skilled in the art should understand that the foregoing implementations are merely intended to describe the present disclosure clearly, rather than to limit the scope of the present disclosure. Those skilled in the art may make other changes or modifications based on the present disclosure, but these changes or modifications should fall within the scope of the present disclosure.

What is claimed is:

1. A detection and gating module in a battery management system, wherein the detection and gating module is configured to detect a voltage of each battery in a battery pack containing N batteries connected in series, N≥1, and the detection and gating module comprises:
N gating switches, wherein an i^{th} gating switch of the N gating switches is connected to a positive terminal of an i^{th} battery of the N batteries, a voltage of the i^{th} battery is detected when the i^{th} gating switch is turned on, and 1≤i≤N;
N protection circuits, wherein an i^{th} protection circuit of the N protection circuits is configured to protect the i^{th} gating switch of the N gating switches; and
N voltage generation circuits, wherein an i^{th} voltage generation circuit of the N voltage generation circuits is configured to generate a turn-on voltage for turning on the i^{th} gating switch of the N gating switches and a turn-off voltage for turning off the i^{th} gating switch.

2. The detection and gating module according to claim 1, wherein when the voltage of the i^{th} battery is detected, battery voltages at two ends of the i^{th} battery are detected by turning on the i^{th} gating switch and an (i−1)^{th} gating switch.

3. The detection and gating module according to claim 2, wherein the i^{th} gating switch comprises a first transistor and a second transistor, a drain of the first transistor is connected to a battery voltage at the positive terminal of the i^{th} battery, a source of the first transistor is connected to a source of the second transistor, a gate of the first transistor is connected to a gate of the second transistor, and a drain of the second transistor outputs a sampled battery voltage.

4. The detection and gating module according to claim 3, wherein the i^{th} protection circuit is a protection diode, a cathode of the i^{th} protection diode is connected to the sources of the first transistor and the second transistor of the i^{th} gating switch, and an anode of the i^{th} protection diode is connected to the gates of the first transistor and the second transistor of the i^{th} gating switch.

5. The detection and gating module according to claim 4, wherein
when the voltage of the i^{th} battery is detected, a control voltage higher than the battery voltage at the positive terminal of the i^{th} battery by a predetermined voltage is generated by the i^{th} voltage generation circuit to turn on the first transistor and the second transistor of the i^{th} gating switch, and a control voltage higher than a battery voltage at a positive terminal of an (i−1)^{th} battery by the predetermined voltage is generated by an (i−1)^{th} voltage generation circuit to turn on a first transistor and a second transistor of the (i−1)^{th} gating switch; and
when the voltage of the i^{th} battery is not detected, a control voltage lower than the battery voltage at the positive terminal of the i^{th} battery is generated by the i^{th} voltage generation circuit to turn off the first transistor and the second transistor of the i^{th} gating switch, and a control voltage lower than the battery voltage at the positive terminal of the (i−1)^{th} battery is generated by the (i−1)^{th} voltage generation circuit to turn off the first transistor and the second transistor of the (i−1)^{th} gating switch.

6. The detection and gating module according to claim 4, wherein
when the voltage of the i^{th} battery is detected, a turn-on voltage for turning on the first transistor and the second transistor of the i^{th} gating switch is generated by the i^{th} voltage generation circuit, and a turn-on voltage for turning on a first transistor and a second transistor of the (i−1)^{th} gating switch is generated by an (i−1)^{th} voltage generation circuit; and
when the voltage of the i^{th} battery is not detected, a turn-off voltage for turning off the first transistor and the second transistor of the i^{th} gating switch is generated by the i^{th} voltage generation circuit, and a turn-off voltage for turning off the first transistor and the second transistor of the (i−1)^{th} gating switch is generated by the (i−1)^{th} voltage generation circuit.

7. The detection and gating module according to claim 5, wherein the i^{th} voltage generation circuit comprises a capacitor, the control voltage is provided by charging and discharging of the capacitor, to turn on or off the first transistor and the second transistor of the i^{th} gating switch.

8. The detection and gating module according to claim 7, wherein in the i^{th} voltage generation circuit,
a drain of a first N-channel metal oxide semiconductor (NMOS) transistor is connected to a highest voltage of the battery pack, a gate of the first NMOS transistor is connected to the battery voltage at the positive terminal of the i^{th} battery, a source of the first NMOS transistor is connected to a drain of a second NMOS transistor, the source of the first NMOS transistor is connected to a cathode of a second diode, the gate of the first NMOS transistor is connected to an anode of the second diode,
a source of the second NMOS transistor is grounded, a drain of a third NMOS transistor is connected to a constant current source, the drain of the third NMOS transistor is connected to a gate of the third NMOS transistor, the gate of the third NMOS transistor is connected to a first terminal of a first switch, a second terminal of the first switch is connected to a gate of the second NMOS transistor, the gate of the second NMOS transistor is connected to a first terminal of a second switch, a second terminal of the second switch is grounded, the drain of the third NMOS transistor is connected to a first terminal of a third switch,
a second terminal of the third switch is connected to a gate of a fourth NMOS transistor, a source of the fourth NMOS transistor is grounded, the gate of the fourth NMOS transistor is connected to a first terminal of a fourth switch, a second terminal of the fourth switch is grounded,
a gate of a first p-channel metal oxide semiconductor (PMOS) transistor is connected to the source of the first NMOS transistor, a source of the first PMOS transistor is connected to the battery voltage at the positive terminal of the i^{th} battery, a drain of the first PMOS transistor is connected to a drain of the fourth NMOS transistor, the drain of the fourth NMOS transistor is connected to a bottom plate of the capacitor,
a top plate of the capacitor is connected to an anode of a first diode, a cathode of the first diode is connected to a supply voltage, and the top plate of the capacitor is connected to the anode of the protection diode.

9. The detection and gating module according to claim 5, wherein in the i^{th} voltage generation circuit,
a drain of a first NMOS transistor is connected to a highest voltage of the battery pack, a gate of the first NMOS transistor is connected to the battery voltage at the positive terminal of the i^{th} battery, a source of the first NMOS transistor is connected to a cathode of a first diode, the gate of the first NMOS transistor is connected to an anode of the first diode, the source of the first NMOS transistor is connected to a drain of a second NMOS transistor,
a source of the second NMOS transistor is grounded, a drain of a third NMOS transistor is connected to a constant current source, the drain of the third NMOS transistor is connected to a gate of the third NMOS transistor, the gate of the third NMOS transistor is connected to a first terminal of a first switch, a second terminal of the first switch is connected to a gate of the second NMOS transistor, the gate of the second NMOS transistor is connected to a first terminal of a second switch, a second terminal of the second switch is grounded, the drain of the third NMOS transistor is connected to a first terminal of a third switch,
a second terminal of the third switch is connected to a gate of a fourth NMOS transistor, a source of the fourth NMOS transistor is grounded, the gate of the fourth NMOS transistor is connected to a first terminal of a fourth switch, a second terminal of the fourth switch is grounded,
a gate of a first PMOS transistor is connected to a gate of a second PMOS transistor, the gate of the first PMOS transistor is connected to a drain of the first PMOS transistor, a source of the first PMOS transistor and a source of the second PMOS transistor are connected to the highest voltage of the battery pack, the drain of the first PMOS transistor is connected to a drain of the fourth NMOS transistor,
a drain of the second PMOS transistor is connected to a source of a third PMOS transistor, a gate of the third PMOS transistor is connected to the battery voltage at the positive terminal of the i^{th} battery, a drain of the third PMOS transistor is grounded, the drain of the second NMOS transistor is connected to the anode of the protection diode, and the source of the third PMOS transistor is connected to the anode of the protection diode.

10. The detection and gating module according to claim 6, wherein the i^{th} voltage generation circuit comprises a fifth NMOS transistor, a drain of the fifth NMOS transistor is connected to the gates of the first transistor and the second transistor, a source of the fifth NMOS transistor is connected to the sources of the first transistor and the second transistor, and a gate of the fifth NMOS transistor is connected to the drain of the fifth NMOS transistor to provide the control voltage through turn-on or turn-off of the fifth NMOS transistor, so as to turn on or off the first transistor and the second transistor of the i^{th} gating switch.

11. The detection and gating module according to claim 10, wherein in the i^{th} voltage generation circuit,
a source of a first PMOS transistor and a source of a second PMOS transistor are connected to a highest voltage of the battery pack, a gate of the first PMOS transistor is connected to a drain of the first PMOS transistor, the gate of the first PMOS transistor is connected to a gate of the second PMOS transistor to form a mirror circuit, the drain of the first PMOS transistor is connected to a drain of a first NMOS transistor,
a source of the first NMOS transistor is grounded, a drain of a second NMOS transistor is connected to a constant current source, the drain of the second NMOS transistor is connected to a gate of the second NMOS transistor, a source of the second NMOS transistor is grounded, the gate of the second NMOS transistor is connected to a first terminal of a first switch, a second terminal of the first switch is connected to a gate of the first NMOS transistor, a first terminal of a second switch is connected to the gate of the first NMOS transistor, a second terminal of the second switch is grounded, the drain of the second NMOS transistor is connected to a first terminal of a third switch,
a second terminal of the third switch is connected to a gate of a third NMOS transistor, a first terminal of a fourth switch is connected to the gate of the third NMOS transistor, a second terminal of the fourth switch is grounded, the drain of the second NMOS transistor is connected to a first terminal of a fifth switch, a second terminal of the fifth switch is connected to a gate of a fourth NMOS transistor, a first terminal of a sixth switch is connected to the gate of the fourth NMOS transistor, a second terminal of the sixth switch is grounded,
a drain of the third NMOS transistor is connected to the source of the fifth NMOS transistor and to the sources of the first transistor and the second transistor, a drain of the fourth NMOS transistor is connected to the drain of the fifth NMOS transistor and to the gates of the first transistor and the second transistor, a drain of the second PMOS transistor is connected to the drain of the fifth NMOS transistor, and the gate of the fifth NMOS transistor is connected to the drain of the fifth NMOS transistor.

12. The detection and gating module according to claim 6, wherein the i^{th} voltage generation circuit comprises a third PMOS transistor, a source of the third PMOS transistor is connected to the gates of the first transistor and the second transistor, a drain of the third PMOS transistor is connected to the sources of the first transistor and the second transistor, and a gate of the third PMOS transistor is connected to the drain of the third PMOS transistor to provide the control voltage through turn-on or turn-off of the third PMOS transistor, so as to turn on or off the first transistor and the second transistor of the i^{th} gating switch.

13. The detection and gating module according to claim 12, wherein in the i^{th} voltage generation circuit,
a source of a first PMOS transistor and a source of a second PMOS transistor are connected to a highest voltage of the battery pack, a gate of the first PMOS transistor is connected to a drain of the first PMOS transistor, the gate of the first PMOS transistor is connected to a gate of the second PMOS transistor to form a mirror circuit, the drain of the first PMOS transistor is connected to a drain of a first NMOS transistor,
a source of the first NMOS transistor is grounded, a drain of a second NMOS transistor is connected to a constant current source, the drain of the second NMOS transistor is connected to a gate of the second NMOS transistor, a source of the second NMOS transistor is grounded, the gate of the second NMOS transistor is connected to a first terminal of a first switch, a second terminal of the first switch is connected to a gate of the first NMOS transistor, a first terminal of a second switch is connected to the gate of the first NMOS transistor, a second terminal of the second switch is grounded, the drain of the second NMOS transistor is connected to a first terminal of a third switch,
a second terminal of the third switch is connected to a gate of a third NMOS transistor, a first terminal of a fourth switch is connected to the gate of the third NMOS transistor, a second terminal of the fourth switch is grounded, the drain of the second NMOS transistor is connected to a first terminal of a fifth switch, a second terminal of the fifth switch is connected to a gate of a fourth NMOS transistor, a first terminal of a sixth switch is connected to the gate of the fourth NMOS transistor, a second terminal of the sixth switch is grounded,
a drain of the third NMOS transistor is connected to the drain of the third PMOS transistor and to the sources of the first transistor and the second transistor, a drain of the fourth NMOS transistor is connected to the source of the third PMOS transistor and to the gates of the first transistor and the second transistor, a drain of the second PMOS transistor is connected to the source of the third PMOS transistor, and the gate of the third PMOS transistor is connected to the drain of the third PMOS transistor.

14. The detection and gating module according to claim 6, wherein the i^{th} voltage generation circuit is the protection diode, and the control voltage is provided by using a reverse breakdown voltage when the protection diode is broken down reversely, to turn on or off the first transistor and the second transistor of the i^{th} gating switch.

15. The detection and gating module according to claim 14, wherein in the i^{th} voltage generation circuit,
a source of a first PMOS transistor and a source of a second PMOS transistor are connected to a highest voltage of the battery pack, a gate of the first PMOS transistor is connected to a drain of the first PMOS transistor, the gate of the first PMOS transistor is connected to a gate of the second PMOS transistor to form a mirror circuit, the drain of the first PMOS transistor is connected to a drain of a first NMOS transistor,
a source of the first NMOS transistor is grounded, a drain of a second NMOS transistor is connected to a constant current source, the drain of the second NMOS transistor is connected to a gate of the second NMOS transistor, a source of the second NMOS transistor is grounded, the gate of the second NMOS transistor is connected to a first terminal of a first switch, a second terminal of the first switch is connected to a gate of the first NMOS transistor, a first terminal of a second switch is connected to the gate of the first NMOS transistor, a second terminal of the second switch is grounded, the drain of the second NMOS transistor is connected to a first terminal of a third switch,
a second terminal of the third switch is connected to a gate of a third NMOS transistor, a first terminal of a fourth switch is connected to the gate of the third NMOS transistor, a second terminal of the fourth switch is grounded, the drain of the second NMOS transistor is connected to a first terminal of a fifth switch, a second terminal of the fifth switch is connected to a gate of a fourth NMOS transistor, a first terminal of a sixth switch is connected to the gate of the fourth NMOS transistor, a second terminal of the sixth switch is grounded,
a drain of the third NMOS transistor is connected to the sources of the first transistor and the second transistor, a drain of the fourth NMOS transistor is connected to the gates of the first transistor and the second transistor, and a drain of the second PMOS transistor is connected to the gates of the first transistor and the second transistor.

16. A battery management system, comprising:
the detection and gating module according to claim 1, wherein the detection and gating module is configured to detect the voltage of each battery in the battery pack containing the N batteries connected in series; and
a voltage amplification module configured to receive the voltage of each battery, wherein the voltage of each battery is output by the detection and gating module, to amplify and output the voltage of each battery.

17. The battery management system according to claim 16, further comprising:
an analog-to-digital conversion module configured to perform an analog-to-digital conversion on the voltage of each battery from the voltage amplification module; and
a control logic module configured to receive a battery voltage converted by the analog-to-digital conversion module, and provide a control signal for a switch driving module at least based on the converted battery voltage, so as' to control turn-on or turn-off of a discharging switch and a charging switch by using the switch driving module.

18. A battery management chip, wherein the battery management chip is integrated with the battery management system according to claim 16.

19. The battery management system according to claim 16, wherein in the detection and gating module, when the voltage of the i^{th} battery is detected, battery voltages at two ends of the i^{th} battery are detected by turning on the i^{th} gating switch and an (i−1)^{th} gating switch.

20. The battery management system according to claim 19, wherein in the detection and gating module, the i^{th} gating switch comprises a first transistor and a second transistor, a drain of the first transistor is connected to a battery voltage at the positive terminal of the i^{th} battery, a source of the first transistor is connected to a source of the second transistor, a gate of the first transistor is connected to a gate of the second transistor, and a drain of the second transistor outputs a sampled battery voltage.
